(19) United States
(12) Patent Application Publication
(10) Pub. No.: US 2022/0045205 A1
(43) Pub. Date: Feb. 10, 2022

(54) TRENCH GATE POWER SWITCH WITH DOPED REGIONS TO INDUCE BREAKDOWN AT SELECTED AREAS

(71) Applicant: Pakal Technologies, Inc., San Francisco, CA (US)

(72) Inventors: Richard A. Blanchard, Los Altos, CA (US); Paul M. Moore, Fremont, CA (US); Vladimir Rodov, Seattle, WA (US); Gary M. Hurtz, San Francisco, CA (US)

(21) Appl. No.: 17/388,350

(22) Filed: Jul. 29, 2021

Related U.S. Application Data
(60) Provisional application No. 63/061,036, filed on Aug. 4, 2020.

(51) Int. Cl. H01L 29/78; H01L 29/06

(52) U.S. Cl. CPC H01L 29/7811; H01L 29/7813; H01L 29/0623

(57) ABSTRACT

A power device is divided into an active area, an active area perimeter, and a termination region. An array of insulated gates formed in trenches form cells in a p-well body, where n+ source regions are formed in the top surface of the silicon wafer and surround the tops of the trenches. A top cathode electrode contacts the source regions, and an anode electrode is on the bottom of the die. A sufficiently high reverse voltage causes a breakdown current to flow between the anode and cathode electrodes. To ensure that a reverse breakdown voltage current occurs away from the gate oxide and/or the termination region, the active area and the active area perimeter of the p-well are additionally doped with p-type dopants to form deep p+ regions in selected areas that extend below the trenches. The deep p+ regions channel the breakdown current away from active cells and the termination region.

### CROSS-REFERENCE TO RELATED APPLICATIONS

This application is based on provisional application Ser. No. 63/061,036, filed Aug. 4, 2020, by Richard Blanchard et al., assigned to the present assignee and incorporated herein by reference.

### FIELD OF THE INVENTION

This invention relates to certain types of insulated gate power devices having gates (e.g., doped polysilicon) formed in etched, oxidized trenches and, in particular, to a technique for forming deep, highly doped regions in selected areas to cause breakdown or breakover in areas away from the gate oxide and termination region to improve ruggedness of the device.

### BACKGROUND

The invention deals with techniques for causing breakdown or breakover (both will be referred to as breakdown for simplicity) to occur in areas away from the gate oxide in trenches. This prevents high energy carriers that occur during the breakdown from tunneling into the gate oxide and possibly shorting out the gates, or changing threshold voltages of the power device (a switch), or changing other characteristics of the power device. The power device normally presents an open circuit to reverse bias voltages across its power terminals. Breakdown occurs when a sufficiently high reverse voltage is applied across the power device's electrodes and the power device effectively forms a current path between the reverse biased terminals. The breakdown voltage is typically specified in the device's data sheet. The device's ability to withstand a breakdown without damage is referred to as ruggedness.

To describe the inventive technique in the context of an insulated gate power device, a particular power device will be described, followed by details of techniques to form deep doped regions to create areas where breakdown occurs which are away from gate oxide in the active area of the power device and away from the termination region surrounding the active area.

Prior art FIG. 1 is a cross-section of a small portion of an insulated trench gate power device 10 reproduced from the assignee's U.S. Pat. No. 9,391,184, incorporated herein by reference. The device 10 may be used as an on/off power switch. The portion is near an edge of the device and shows a plurality of cells having vertical gates 12 formed in insulated trenches. A 2-dimensional array of the cells may be formed in a common p-well 14, and the cells are connected in parallel. The area away from the edge, having the active cells, is referred to as the active area.

The edge of the device suffers from field crowding, and the edge cell is modified to increase ruggedness of the device. The edge cell has an opening 16 in the n+ source region 18 where the cathode electrode 20 shorts the n+ source region 18 to the p-well 14. Such shorting increases the tolerance to transients to prevent unwanted turn on and prevents the formation of hot spots. The configuration of the edge cell may also be used in other cells of the device for a more uniform current flow across the device.

Trenches 15 are etched in the surface of the silicon wafer, and the sidewalls of the trench 15 are oxidized to form an oxide layer 22. Doped polysilicon is deposited in the trenches 15 using CVD to form vertical gates 12. The vertical gates 12 are insulated from the p-well 14 by the oxide layer 22. The narrow gates 12 (doped polysilicon) are connected together outside the plane of the drawing and are coupled to a gate voltage via the gate electrode 25 contacting the polysilicon portion 28. A patterned dielectric layer 26 insulates the metal from the various regions. The guard rings 29 at the edge of the cell, in a termination region, reduce field crowding for increasing the breakdown voltage.

An npnp semiconductor layered structure is formed. There is a bipolar pnp transistor formed by a p+ substrate 30, an n− epitaxial (epi) layer 32, and the p-well 14. There is also a bipolar npn transistor formed by the n-epi layer 32, the p-well 14, and the n+ source region 18. An n-type buffer layer 35, with a dopant concentration higher than that of the n-epi layer 32, reduces the injection of holes into the n-epi layer 32 from the p+ substrate 30 when the device is conducting. It also reduces the electric field at the anode pn-junction when the power device 10 is reverse biased. A bottom anode electrode 36 contacts the p+ substrate 30, and a cathode electrode 20 contacts the n+ source region 18. The p-well 14 surrounds the gate structure, and the n-epi layer 32 extends to the surface around the p-well 14.

When the anode electrode 36 is forward biased with respect to the cathode electrode 20, but without a sufficiently positive gate bias, there is no current flow, since the product of the betas (gains) of the pnp and npn transistors is less than one (i.e., there is no regeneration activity).

When the gate is forward biased, electrons from the n+ source region 18 become the majority carriers along the gate sidewalls and below the bottom of the trenches in an inversion layer, causing the effective width of the npn base (the portion of the p-well 14 between the p-layers) to be reduced. As a result, the beta of the npn transistor increases to cause the product of the betas to exceed one. This condition results in “breakover,” when holes are injected into the lightly doped n-epi layer 32 and electrons are injected into the p-well 14 to fully turn on the device. Accordingly, the gate bias initiates the turn-on, and the full turn-on (due to regenerative action) occurs when there is current flow through the npn transistor as well as current flow through the pnp transistor.

When the gate bias is removed, such as the gate electrode 25 being shorted to the cathode electrode 20, the device 10 turns off.

The device 10 is similar to many other types of high current/high voltage insulated gate power devices in that it is cellular and the thin gate oxide on the trench sidewalls is susceptible to damage when a breakdown occurs.

When the voltage across the device 10 is reversed, such as due to a transient condition or if the device 10 is used as a rectifier, and the voltage is less than a breakdown voltage, a depletion layer is created in the n-epi layer 32 where there are no free carriers. The dashed line 19 represents the bottom boundary of the depletion layer into the n-epi layer 32. The top boundary (not shown) of the depletion layer extends into the p-well 14. As the reverse voltage increases, the depletion layer extends downward, toward the p+ substrate 30, and to the edge, such as past the first guard ring 29. However, with a higher reverse voltage, when the depletion layer generally reaches the p+ substrate 30 or before such time, breakdown occurs and there is a reverse current flow.

Some issues regarding breakdown of the power device 10 are that: 1) the breakdown may occur in the active (center) area of the device 10 where the gate oxide 22 can be damaged by high energy carriers, or carriers can tunnel into the gate oxide 22 and decrease the threshold voltage of the MOS device; and 2) the breakdown may occur in the termination region, where there is no source/cathode (top) electrode to conduct the reverse current, resulting in high heat being generated in the termination region, possibly causing damage.

Therefore, what is needed is a technique to cause breakdown to occur in selected areas, including away from the termination region, that avoid gate oxide damage and excess heat being generated in the termination region.

U.S. Pat. No. 5,998,836 to Williams, incorporated herein by reference, describes a vertical MOSFET having a vertical n-channel between two n layers. Williams' representative figure is substantially reproduced herein as FIG. 2, and the various labeled elements will not be described in detail herein. Only the pertinent elements will be discussed. The Williams MOSFET has top n+ source regions 34 formed in a p-body 33. Trenched gates 31 extend through the p-body 33 and into an n-epi layer 17. When the gate 31 is biased positive, an n-channel along the gate 31 creates a current path between the top n+ source 34 and the n-epi layer 17. Williams adds a deep p+ region 38 in some cells that is connected to the top source electrode 41, which makes those cells inactive, so that the pn diode formed by the deep p+ region 38 and the n-epi layer 17 (formed over an n+ substrate 13) is in parallel with the n-channel. With a reverse voltage applied to the MOSFET, the pn diode conducts to clamp the reverse voltage across the MOSFET. Williams states in the Summary section: “The diode operates as a voltage clamp and thereby limits the voltage across the gate oxide layer, particularly in embodiments wherein the trenches extend into the substrate and the gate oxide must support the entire voltage drop across the MOSFET.”

The Williams structure is very different from the device of Applicant's FIG. 1 since, in FIG. 1, there is no pn diode between the anode and cathode electrodes due to Applicant's p+ substrate 30 and the fact that the trench gates 12 do not extend into the n-epi layer 32. Accordingly, the basic principles of operation of the Williams MOSFET, with the deep p+ region 38 creating a voltage clamp, do not apply to Applicant's device.

Also, note that the Williams deep p+ region 38 is only located in the active area of the MOSFET, since that is the only area where it is necessary to perform its function as a clamp.

Further, Williams is silent about how to ensure that breakdown occurs away from the termination region.

### SUMMARY

A power device is divided into an active area (typically the center part of the die), an active area perimeter (the edge of the active area), and a termination region (including the guard rings). An array of insulated gates formed in trenches form cells, where n+ source regions are formed in the top surface of the silicon wafer and surround the tops of the trenches. A top cathode electrode contacts the source regions. An anode is typically at the bottom of the die to form a vertical power switch. A bottom anode electrode contacts the anode (a p+ substrate). The trenches and n+ source regions are formed in a p-well body. The trenches terminate within the p-well so there is no vertical MOSFET formed where a vertical n-channel exists between two n layers. In a forward biased device, a positive voltage is applied to the anode electrode, and the cathode electrode may be directly connected to ground or may be connected to ground through a load.

In another embodiment, the anode electrode may also be formed on the top of the die, and electrically connects to a deep buried region that laterally conducts current to a sinker connected to the anode electrode. Thus, the present invention applies to vertical and lateral devices.

If the voltage is reversed, a depletion layer forms and, if the reverse voltage is high enough, breakdown can occur. In a conventional design, the breakdown may occur in the active area (near the gate oxide) or in the termination region (where there is no power electrode), causing the problems previously discussed.

To ensure that the breakdown occurs away from the gate oxide and/or the termination region, the p-well is additionally doped with p-type dopants to form a deep p+ region in selected areas that extends below the trenches. The top surfaces of the deep p+ regions are contacted by the source/cathode electrode to remove the reverse current carriers. In this way, a breakdown in the active area will occur only in places where the deep p+ regions are formed, and the reverse current carriers are channeled away from the trenches and gate oxide by the low conductivity path through the deep p+ regions. Although forming the deep p+ regions sacrifices a current-conducting cell, the reduced current conduction is not significant if the deep p+ regions are scattered throughout the active area. Having the breakdown occur in the active area is also beneficial since there is good heat dissipation through the top metal electrode.

To prevent breakdown occurring in the termination region, the active area perimeter (adjacent to the termination region) contains one or more deep p+ regions in the p-well that completely surround the active area. Therefore, instead of any breakdown occurring in the termination region, the breakdown occurs through the deep p+ regions in the active area perimeter.

These concepts apply to various types of insulated trench gate power devices.

Other embodiments are disclosed.

Unlike the Williams device, previously discussed, Applicant's deep p+ region does not form a pn diode between the top and bottom electrodes, since Applicant's device has a p+ substrate. So the deep p+ region forms a pnp structure (not a pn diode) in conjunction with the n-epi layer and the p+ substrate. Applicant's deep p+ region therefore does not act as diode clamp in reverse voltage situations and involves very different concepts.

### BRIEF DESCRIPTION OF THE DRAWINGS

FIG. 1 is copied from Applicant's U.S. Pat. No. 9,391,184, except a sample depletion region boundary 19 has been added. FIG. 1 is a cross-section of a vertical power device having trench gates connected in parallel. This device uses an n-MOS to turn on devices in the cells.

FIG. 2 is copied from U.S. Pat. No. 5,998,836 to Williams and shows a vertical MOSFET with added clamp diodes distributed in the active area of the MOSFET for clamping a reverse voltage.

FIG. 3 illustrates a modification to the device of FIG. 1, where deep p+ regions have been distributed in the active area and deep p+ regions are formed in the active area perimeter to substantially surround the active area. Breakdown only occurs at one or more of the deep p+ regions.

FIG. 4 is a top down view of an array of cells in an active area of the power device, where active cells (current carrying cells) have a trench gate adjacent to an n+ source region, and inactive cells, where breakdown occurs, replace the n+ source region with a deep p+ region.

FIG. 5 is a top down view of an active area perimeter, where all the cells are inactive, since all the trenches are adjacent to deep p+ regions where breakdown occurs.

FIG. 6 is similar to FIG. 5 but, instead of the deep p+ regions being arranged side by side (surrounding the active area), the deep p+ regions are staggered to improve performance.

FIG. 7 is a cross-sectional view of the active area perimeter and the termination region of a power device that may be similar to that of FIG. 1, where the device has been modified to add deep p+ regions in the active area perimeter.

Elements that are the same or equivalent in the various figures may be labeled with the same numeral.

### DETAILED DESCRIPTION

Although the techniques of the present invention can be used for various applications, a few examples will be given with reference to power devices that have trench gates formed in a p-well, where the p-well contains the active area. The conductivity types may be reversed in all embodiments.

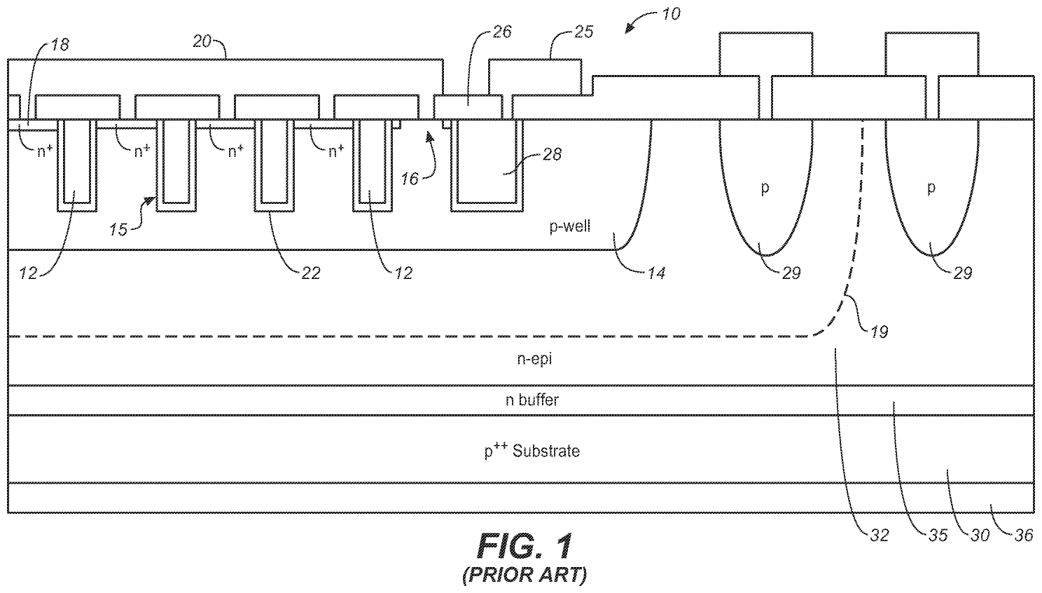

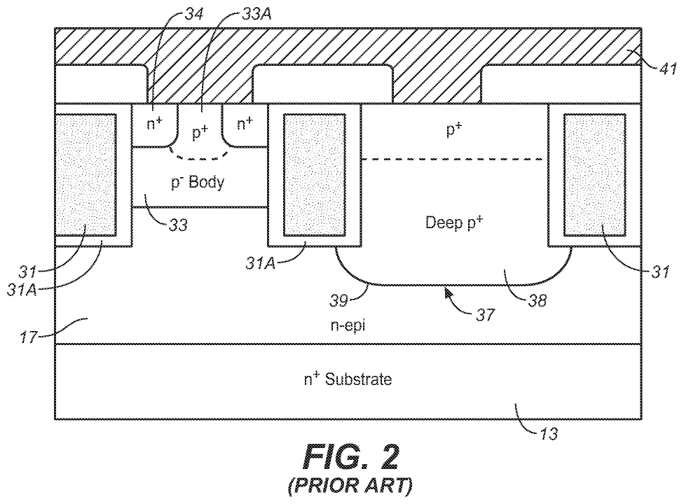

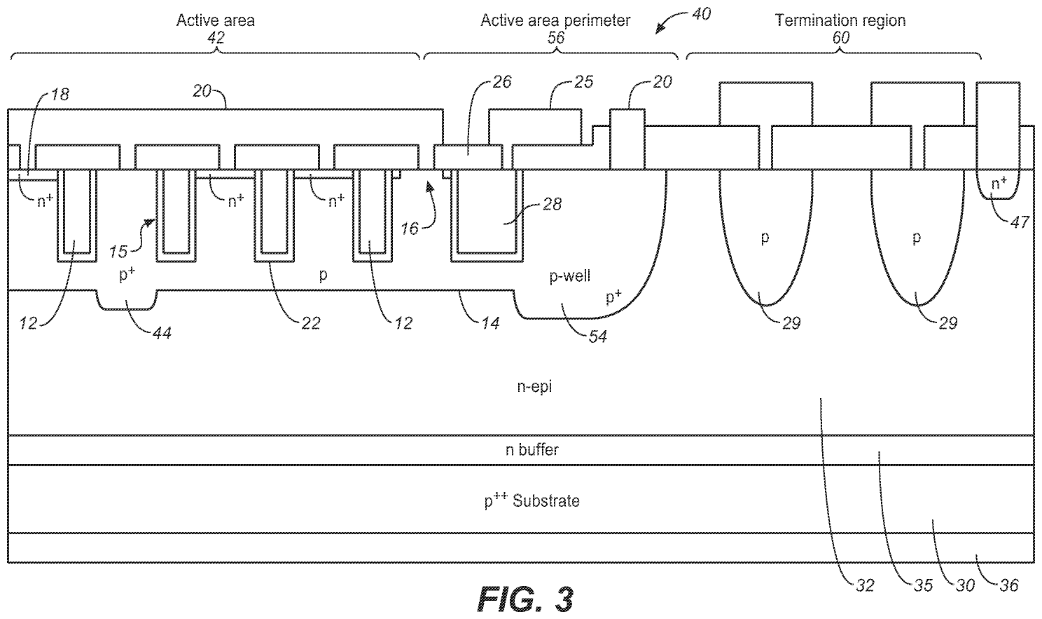

FIG. 3 illustrates a modification to the power device 10 of FIG. 1 to improve the ruggedness of the device to breakdown occurrences.

In the power device 40, masks for the n-source implantation are modified to block the implantation of n-type dopants into certain cells in the active area 42. Those certain cells are inactive and will be where breakdown is more likely to occur.

A p-dopant implant mask then only exposes the silicon in the cells where deep p+ regions 44 are to be formed. P-type dopants, such as boron, are then implanted and annealed or diffused to cause the resulting p+ regions 44 to extend at least below the trenches 15 in the active area 42. In the example, the p+ regions 44 extend below the p-well 14.

FIG. 3 also includes an n+ EQR (equipotential ring) 47 at the outer edge of the die. FIG. 1 would also include a similar EQR 47. The EQR 47 may be connected to a floating metal.

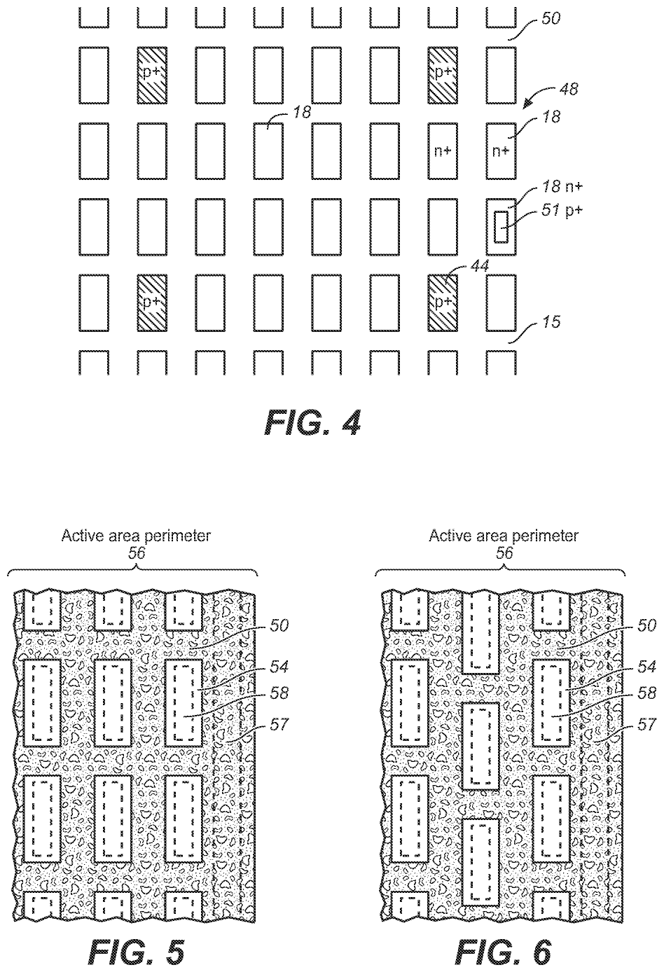

FIG. 4 is a top down view of an array of cells 48 in the active area 42 of the power device 40, where active cells (current carrying cells) have a trench gate (doped polysilicon 50) adjacent to an n+ source region 18 and may include distributed p+ body contact regions 51. The active area 42 also includes inactive cells, where breakdown occurs, where the n+ source region 18 is replaced with a deep p+ region 44. The distribution of the deep p+ regions 44 is selected to ensure that breakdown occurs through the p+ regions 44, yet there is not a significant decrease in forward current due to the sacrifice of active cell areas. Simulation may be used to select the optimal distribution of the deep p+ regions 44. In the example, 1 in 5 cells in the horizontal direction is converted, and 1 in 3 cells in the vertical direction are converted, so about one out of 15 cells are converted to the inactive cells, but the percentage can be more or less. In one embodiment, the converted (inactive) cells make up less than one-tenth of the cells in the active area. The selection of which cells to convert to the deep p+ regions depends on the maximum allowable current to be withstood during the breakdown period.

To prevent breakdown in the termination region 60 (FIG. 3), a deep p+ region 54 is formed near or at the edge of the p-well 14 in the active area perimeter 56. The deep p+ region 54 essentially surrounds the active area 42. The deep p+ region 54 is contacted by the same cathode electrode 20 that contacts the deep p+ regions 44 in the active area 42. Multiple rings of the deep p+ regions 54 may be used. The deep p+ regions 54 in the active area perimeter 56 may be continuous or segmented. Although FIG. 3 shows the deep p+ region 54 at the end of the p-well 14, the deep p+ region 54 can be located between the end of the p-well 14 and the gate contact trench.

Due to the p+ regions 44 and 54, the depletion region boundary (in the n-epi layer 32 or n buffer layer 35) under those regions bulges downward toward the p+ substrate 30 in the event of a reverse voltage. Breakdown generally occurs at the depletion region areas that are closest to the p+ substrate 30. Therefore, the areas in which breakdown occurs can be selected by the locations of the deep p+ regions.

FIG. 5 is a top down view of the active area perimeter 56, where all the cells are inactive, since all the trenches (filled with insulated polysilicon 50) are adjacent to deep p+ regions 54 where breakdown occurs. The deep p+ regions 54 are connected to the cathode electrode 20 via openings 58 in a patterned dielectric layer. The deep p+ regions 54 are shown arranged in rows and columns. The polysilicon 50 in all the trenches is electrically connected together. A metal gate electrode may contact the gate polysilicon in the trenches within a contact area 57 identified with a dashed line. Therefore, the gate electrode is outside of the cathode electrode portion that contacts the deep p+ regions 54.

FIG. 6 is similar to FIG. 5 but the deep p+ regions 54 are staggered to improve the likelihood that breakdown will occur via one or more of the deep p+ regions 54 rather than in the termination region 60 (FIG. 3).

Alternatively, the deep p+ region 54 in the perimeter 56 can be continuous around the active area 42.

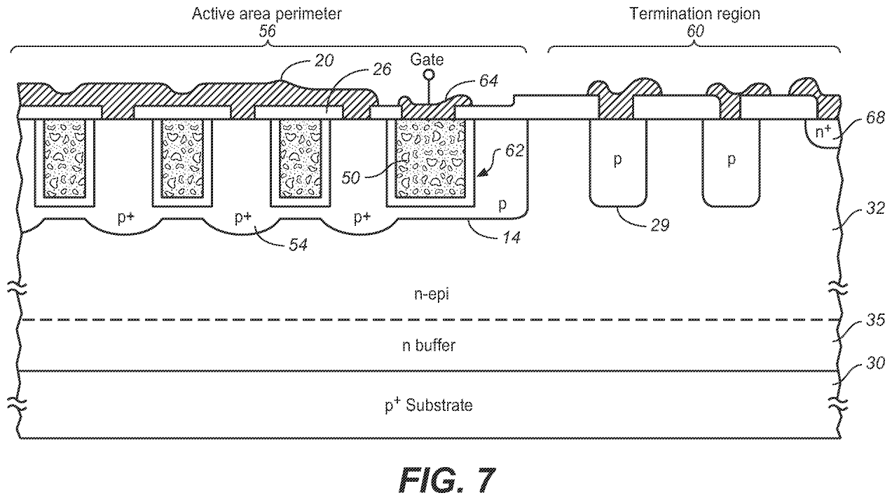

FIG. 7 is a cross-sectional view of the active area perimeter 56 and the termination region 60 of a power device that may be similar to that of FIG. 1 or FIG. 3, where the cross-section cuts across three deep p+ regions 54 in the active area perimeter 56 as well as the polysilicon 50 in a trench 62 that serves to electrically connect all the polysilicon in the device to a gate electrode 64. The gate electrode 64 may be formed during the same metallization step that forms the cathode electrode 20, so there is no need for two levels of metal for the gate electrode and cathode electrode.

The number and spacing of the guard rings 29 (or field limiting rings) result in a breakdown voltage in the termination area 60 that is higher than the breakdown voltage through the deep p+ regions 44 and 54, to ensure the breakdown does not occur in the termination region 60.

An n+ region 68 may be contacted by a floating metal to provide an EQR at the die perimeter.

In another embodiment, the “bottom” anode electrode may instead be formed on the top of the die and electrically connects to a deep buried p+ region that laterally conducts current to a p+ sinker connected to the anode electrode. Or, the sinker may extend down to the p+ substrate. Thus, the present invention applies to both vertical and lateral devices.

The various concepts described can be applied to any type of trench-gate device to improve the ruggedness of the device in response to a breakdown (includes breakover) condition.

Various features disclosed may be combined to achieve a desired result.

While particular embodiments of the present invention have been shown and described, it will be obvious to those skilled in the art that changes and modifications may be made without departing from this invention in its broader aspects and, therefore, the appended claims are to encompass within their scope all such changes and modifications as fall within the true spirit and scope of this invention.

What is claimed is:

1. An insulated trench gate device comprising:
a first layer of a first conductivity type, the first layer having a first concentration of dopants of the first conductivity type;
trenches formed in the first layer so as to terminate in the first layer;
a gate oxide along sidewalls of the trenches;
a first conductive material at least partially filling the trenches to form gates;
first regions of a second conductivity type adjacent to and near the tops of at least some of the trenches in an active area of the device;
a top first electrode electrically contacting the first regions;
a second layer of the second conductivity type below the first layer;
a third layer of the first conductivity type below the second layer; and
second regions of the first conductivity type formed in the first layer that extend below the trenches in the active area, the second regions being electrically connected to the first electrode, the second regions having a second dopant concentration that is higher than the first dopant concentration.

2. The device of claim 1 wherein the first layer is a well formed in the second layer.

3. The device of claim 1 wherein the second regions conduct a breakdown voltage current when a sufficiently high reverse voltage is applied across the device.

4. The device of claim 1 wherein the second regions are formed in inactive cells of the device where no first regions are adjacent to the trenches.

5. The device of claim 1 wherein the device includes the active area that conducts current when the device is on, an active area perimeter, and a termination region, wherein the second regions are formed in both the active area and the active area perimeter.

6. The device of claim 5 wherein the first layer is a well formed in the second layer and where the second regions are formed at or near an outer perimeter of the well.

7. The device of claim 6 wherein the second regions formed at or near the outer perimeter of the well surround the active area.

8. The device of claim 7, wherein the second regions are formed in segments that surround the active area.

9. The device of claim 8 wherein the segments form concentric rings around the active area.

10. The device of claim 9 wherein the segments in one ring are staggered with respect to the segments in another ring.

11. The device of claim 1 wherein the second regions are distributed around the active area.

12. The device of claim 1 where the active area comprises cells, each cell having a gate, where cells having the second regions are inactive cells, and where the inactive cells make up less than 10 percent of the cells in the active area.

13. The device of claim 1 wherein the trenches are totally formed in the first layer.

14. The device of claim 1 wherein the second regions extend below the first layer.

15. The device of claim 14 further comprising a third layer of the first conductivity type below the second layer of the second conductivity type.

16. The device of claim 1 wherein the second regions are formed in an active area of the device and in an active area perimeter of the device, wherein cells in the active area perimeter are all inactive, and wherein a gate electrode electrically contacts the first conductive material in the trenches in an area outside of all the second regions in the active area perimeter.

17. The device of claim 1 wherein the first layer is a p-type well, the second layer is an n-type epitaxial layer, the first regions are highly doped n+ type regions formed in a surface of the p-well, and the second regions are highly doped p+ regions extending through the p-well.

18. The device of claim 1 wherein the device comprises the active area, containing active cells, and active area perimeter, containing inactive cells, and a termination region, wherein the second regions cause a breakdown voltage current to occur away from the termination region.

19. The device of claim 18 wherein the second regions also cause the breakdown voltage current to occur away from the gate oxide in active cells in the active region.

20. An insulated trench gate device formed in a die comprising:
active cells in an active area of the device;
inactive cells in an active area perimeter surrounding the active area;
a termination region between the active area perimeter and an edge of the die;
a first layer of a first conductivity type, the first layer having a first concentration of dopants of the first conductivity type;
trenches formed in the first layer;
a gate oxide along sidewalls of the trenches;
a first conductive material at least partially filling the trenches to form gates;
first regions of a second conductivity type adjacent to and near tops of at least some of the trenches in the active area of the device;
a top first electrode electrically contacting the first regions;
a second layer of the second conductivity type below the first layer; and
second regions of the first conductivity type formed in the first layer that extend below the trenches in the active area perimeter, the second regions being electrically connected to the first electrode, the second regions having a second dopant concentration that is higher than the first dopant concentration.

21. The device of claim 20 wherein the trenches are formed so as to terminate in the first layer.

22. The device of claim 21 further comprising a third layer of the first conductivity type below the second layer.

23. The device of claim 20 wherein the second regions are also formed in the active area.

24. The device of claim 20 wherein the second regions for concentric rings around the active area.

25. The device of claim 20 wherein the concentric rings are formed by segments, wherein the segments in one ring are staggered with respect to segments in another ring.

26. The device of claim 20 wherein the second regions conduct a breakdown voltage current when a sufficiently high reverse voltage is applied across the device.
